(19) United States
(12) Patent Application Publication
(10) Pub. No.: US 2012/0008276 A1
(43) Pub. Date: Jan. 12, 2012

(54) AIR DUCT AND ELECTRONIC DEVICE USING THE SAME

(75) Inventor: HAO-DER CHENG, Tu-Cheng (TW)

(73) Assignee: HON HAI PRECISION INDUSTRY CO., LTD., Tu-Cheng (TW)

(21) Appl. No.: 12/909,804

(22) Filed: Oct. 21, 2010

(30) Foreign Application Priority Data
Jul. 7, 2010 (TW) 99122264

(51) Int. Cl. G06F 1/20; H05K 7/20

(52) U.S. Cl. 361/679.48; 361/695

(57) ABSTRACT

An exemplary electronic device includes a circuit board, an air duct and a cooling fan. The circuit board includes a first electronic component and a second electronic component formed thereon. The air duct defines a first air vent and a second air vent at opposite ends thereof. The cooling fan is located on the circuit board and faces the second air vent. The first electronic component is disposed in the air duct. The second electronic component is disposed outside the air duct and adjacent to the air duct. The air duct defines an opening therethrough corresponding to the second electronic component.

### CROSS-REFERENCE TO RELATED APPLICATION

This application is related to a co-pending application entitled “AIR DUCT AND ELECTRONIC DEVICE INCORPORATING THE SAME” (attorney docket number US33914), assigned to the same assignee of this application and filed on the same date as this application. The related application is incorporated herein by reference.

### BACKGROUND

1. Technical Field

The disclosure generally relates to an air duct for cooling a plurality of electronic components, and an electronic device using the air duct.

2. Description of Related Art

It is well known that heat is generated by many kinds of electronic components, such as integrated circuit chips and memory cards, during their operation. If the heat is not efficiently removed, the electronic components may suffer damage. Typically, a cooling fan is provided to produce airflow over and through the electronic components. An air duct may also be provided to cover one of the electronic components and guide the airflow to cool the electronic component in the air duct. However, in such arrangement, other electronic components outside the air duct cannot be cooled.

What is needed, therefore, is an air duct and an electronic device using the air duct which can overcome the described limitations.

### BRIEF DESCRIPTION OF THE DRAWINGS

Many aspects of the present embodiments can be better understood with reference to the accompanying drawings. The components in the drawings are not necessarily drawn to scale, the emphasis instead placed upon clearly illustrating the principles of the present embodiments. Moreover, in the drawings, like reference numerals designate corresponding parts throughout the various views.

FIG. 1 is a schematic, top plan view of an electronic device in accordance with a first embodiment of the disclosure.

FIG. 2 is an enlarged, isometric view of an air duct of the electronic device shown in FIG. 1.

FIG. 3 is a schematic, top plan view of an electronic device in accordance with a second embodiment of the disclosure.

### DETAILED DESCRIPTION

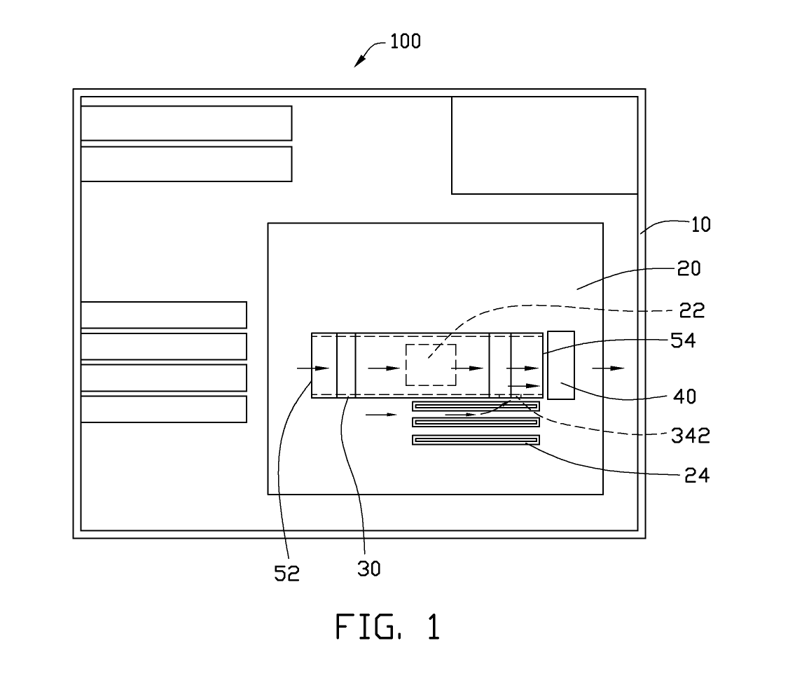

Referring to FIG. 1, an electronic device 100 in accordance with a first embodiment of the disclosure is shown. The electronic device 100 can be a computer, a server or other. The electronic device 100 includes a system enclosure 10, a circuit board 20, an air duct 30 and a cooling fan 40.

The circuit board 20 has a plurality of electronic components provided thereon. In this embodiment, a first electronic component, such as a CPU 22, and a group of second electronic components, such as expansion cards 24 (e.g., graphics cards, memory cards, etc), are mounted on the circuit board 20. The expansion cards 24 are parallel to and spaced from each other. A bottom end of each of the expansion cards 24 is received in a peripheral component interconnect (PCI) slot (not labeled) mounted on the circuit board 20.

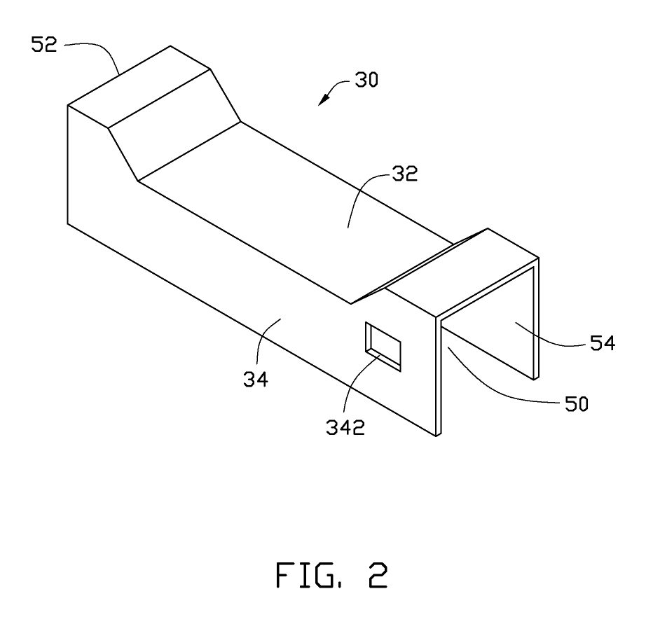

The air duct 30 is mounted on the circuit board 20. The CPU 22 is disposed inside the air duct 30, and the expansion cards 24 are disposed outside the air duct 30. Referring to FIG. 2, a transverse section of the air duct 30 is substantially U-shaped. The air duct 30 includes a top plate 32, and two side plates 34 depending from opposite sides of the top plate 32, respectively. Alternatively, the air duct 30 can be a hollow cylinder, a curved bridge, or another shape. The top plate 32 and the side plates 34 cooperatively define an air passage 50 therebetween. The air duct 30 defines a first air vent and a second air vent at opposite ends of the air passage 50, respectively. In this embodiment, the first air vent farthest from the expansion cards 24 functions as an air inlet 52, and the second air vent adjacent to the expansion cards 24 functions as an air outlet 54. The top plate 32 has a saddle shape, with a middle portion thereof located lower than two end portions thereof. Two sloped portions of the top plate 32 are located between ends of the middle portion and the two end portions. The air duct 30 defines an opening 342 in one of the side plates 34 facing the expansion cards 24. The opening 342 is located adjacent to the air outlet 54. The opening 342 is higher than the expansion cards 24, thereby preventing the expansion cards 24 from blocking the opening 342 after installation of the expansion cards 24 on the circuit board 20.

The cooling fan 40 is mounted on the circuit board 20 at the air outlet 54 of the air duct 30, and is for drawing airflow out of the air duct 30 through the air outlet 54.

Referring back to FIG. 1, during operation of the cooling fan 40, air is drawn into the air passage 50 through the air inlet 52 of the air duct 30 by the cooling fan 40, and such airflow carries heat generated by the CPU 22 in the air duct 30 toward the air outlet 54. Additional air is drawn through the expansion cards 24 adjacent to the opening 342 of the air duct 30 by the cooling fan 40, and such airflow carries heat generated by the expansion cards 24. The additional air enters the air passage 50 through the opening 342 and proceeds toward the air outlet 54. The air flowing toward the air outlet 54 is drawn out of the air duct 30 by the cooling fan 40.

In the electronic device 100, the opening 342 is defined in the air duct 30 adjacent to the expansion cards 24. Therefore the heat generated by the expansion cards 24 can be taken away by the air flowing through the opening 342, preventing damage of the expansion cards 24 due to overheating. This improves the heat dissipation efficiency of the electronic device 100. In addition, the opening 342 is defined in the air duct 30 adjacent to the air outlet 54, namely, adjacent to the cooling fan 40. Therefore, a velocity of the air flowing through the opening 342 is enhanced, and thus the heat generated by the expansion cards 24 can be taken away more easily.

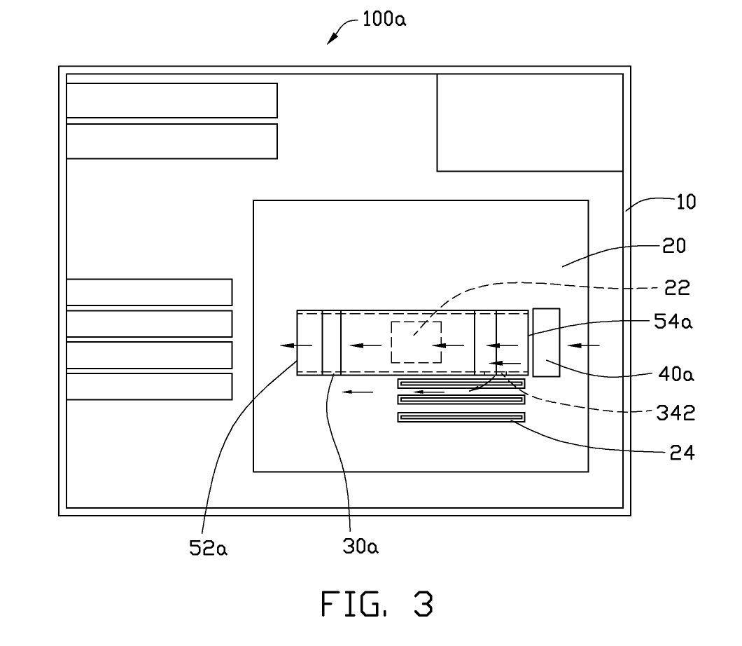

Referring to FIG. 3, an electronic device 100a in accordance with a second embodiment of the disclosure is shown. The electronic device 100a differs from the electronic device 100 of the first embodiment only in that a cooling fan 40a produces airflow toward an air duct 30a. At this time, the second air vent of the air duct 30a functions as an air inlet 54a, and the first air vent of the air duct 30a functions as an air outlet 52a. During operation, airflow produced by the cooling fan 40a enters the air passage 50 through the air inlet 54a. A portion of the air flowing into the air passage 50 flows directly toward the CPU 22, evacuates heat generated by the CPU 22, and finally exhausts out of the air duct 30a through the air outlet 52a. Another portion of the air flowing into the air passage 50 flows toward the expansion cards 24 through the opening 342, and evacuates heat generated by the expansion cards 24.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An electronic device comprising:
a circuit board comprising a first electronic component and a second electronic component mounted thereon;
an air duct defining a first air vent and a second air vent at opposite ends thereof, respectively; and
a cooling fan located on the circuit board and facing the second air vent, the first electronic component disposed in the air duct, the second electronic component disposed outside the air duct and adjacent to the air duct, the air duct defining an opening therethrough corresponding to the second electronic component.

2. The electronic device of claim 1, wherein the opening is located closer to the second air vent than the first air vent.

3. The electronic device of claim 1, wherein the cooling fan draws airflow out of the air duct through the second air vent, the second air vent functioning as an air outlet, and the first air vent as an air inlet.

4. The electronic device of claim 1, wherein the cooling fan produces airflow toward the second air vent, the second air vent functioning as an air inlet, and the first air vent as an air outlet.

5. The electronic device of claim 1, wherein the air duct comprises a top plate and two side plates depending from opposite sides of the top plate, respectively, and the opening is defined in one of the side plates adjacent to the second electronic component.

6. The electronic device of claim 5, wherein the top plate has a saddle shape, with a middle portion thereof located lower than two end portions thereof.

7. The electronic device of claim 1, wherein the opening is higher than the second electronic component.

8. The electronic device of claim 1, wherein the first electronic component is a CPU, and the second electronic component is an expansion card.

9. An electronic device comprising:
an air duct comprising a top plate and two side plates depending from the top plate, the top plate and the side plates cooperatively defining an air passage therebetween, the air duct defining a first air vent and a second air vent at opposite ends of the air passage, respectively, wherein one of the side plates defines an opening in communication with the air passage and with an exterior of the air duct;
a first electronic component arranged in the air passage of the air duct;
a second electronic component arranged at the exterior of the air duct and facing the opening; and
a cooling fan producing airflow through the air duct and the opening to cool the first electronic component and the second electronic component simultaneously.

10. The electronic device of claim 9, wherein the cooling fan faces the second air vent, and the opening is located adjacent to the second air vent.

11. The electronic device of claim 9, wherein the cooling fan draws airflow out of the air duct through the second air vent, the second air vent functioning as an air outlet, and the first air vent as an air inlet.

12. The electronic device of claim 9, wherein the cooling fan produces airflow toward the second air vent, the second air vent functioning as an air inlet, and the first air vent as an air outlet.

13. The electronic device of claim 9, wherein the top plate has a saddle shape, with a middle portion thereof located lower than two end portions thereof.

14. The electronic device of claim 9, wherein the opening is higher than the second electronic component.

15. The electronic device of claim 9, wherein the first electronic component is a CPU, and the second electronic component is an expansion card.

16. An air duct for cooling a plurality of electronic components, the air duct comprising:
a top plate; and
two side plates depending from opposite lateral sides of the top plate, respectively, the top plate and the two side plates cooperatively defining a first air vent and a second air vent at opposite ends of the air duct, one of the side plates defining an opening configured for allowing air to flow therethrough to cool at least one of the electronic components located outside of the air duct and adjacent to the opening.

17. The air duct of claim 16, wherein the opening is located adjacent to one of the first and second air vents.

18. The air duct of claim 16, wherein the first air vent functions as an air outlet, and the second air vent function as an air inlet.

19. The air duct of claim 16, wherein the first air vent functions as an air inlet, and the second air vent functions as an air outlet.

20. The air duct of claim 16, wherein the top plate has a saddle shape, with a middle portion thereof located lower than two end portions thereof.
